(19) United States
(12) Patent Application Publication
(10) Pub. No.: US 2026/0144174 A1
(43) Pub. Date: May 21, 2026

(54) METHODS OF BONDING A SEMICONDUCTOR ELEMENT TO A SUBSTRATE, AND RELATED SYSTEMS

(71) Applicant: Kulicke and Soffa Industries, Inc., Fort Washington, PA (US)

(72) Inventors: Urban Ernst, Konstanz (DE); Andreas Marte, Steinach (CH)

(73) Assignee: Kulicke and Soffa Industries, Inc., Fort Washington, PA (US)

(21) Appl. No.: 19/383,954

(22) Filed: Nov. 10, 2025

Related U.S. Application Data
(60) Provisional application No. 63/722,699, filed on Nov. 20, 2024.

(51) Int. Cl. H01L 23/00

(52) U.S. Cl. CPC H10W 99/00; H10W 72/011; H10W 72/019; H10W 72/071; H10W 80/161; H10W 80/163; H10W 80/312; H10W 80/327

(57) ABSTRACT

A method of bonding a semiconductor element to a substrate is provided. The method includes the steps of: (a) supporting the substrate with a support structure, the substrate including a first substrate fiducial; (b) moving a bond head assembly to an offset position such that a first semiconductor element fiducial of the semiconductor element is offset from the first substrate fiducial, the semiconductor element being carried by a bonding tool of the bond head assembly; (c) imaging the first semiconductor element fiducial and the first substrate fiducial with an imaging system of the bond head assembly with the bond head assembly at the offset position; (d) moving the semiconductor element while it is carried by the bonding tool such that the first semiconductor element fiducial is aligned with the first substrate fiducial; and (e) bonding the semiconductor element to the substrate after step (d).

### CROSS-REFERENCE TO RELATED APPLICATION

This application claims the benefit of U.S. Provisional Application No. 63/722,699, filed Nov. 20, 2024, the content of which is incorporated herein by reference.

### FIELD

The invention relates to systems and methods of bonding a semiconductor element to a substrate.

### BACKGROUND

Flip chip bonding is a well-known form of die bonding (also referred to as die attach). Due to trends of decreasing interconnect pitch, flip chip applications continuously target improved placement accuracy.

Hybrid bonding is an emerging advanced packaging technology, utilizing flip chip bonding. Exemplary placement accuracy specifications in hybrid bonding are currently as low as 50 nm at 3σ. Typical die handling techniques, and alignment techniques, in conventional flip chip bonding schemes do not allow for that level of accuracy.

Certain alignment schemes used to align semiconductor elements to substrates are described in U.S. Pat. No. 12,438,117 (“DIE BONDING SYSTEMS, AND METHODS OF USING THE SAME”), which is hereby incorporated by reference. U.S. Pat. No. 12,438,117 generally describes an alignment method where the “bottom side” die fiducials and the target substrate fiducials are imaged at the same time (e.g., by means of an infrared illumination, where the infrared illumination passes through the die).

It would be desirable to provide improved bonding systems and methods of using such bonding systems.

### SUMMARY

According to an exemplary embodiment of the invention, a method of bonding a semiconductor element to a substrate is provided. The method includes the steps of: (a) supporting the substrate with a support structure, the substrate including a first substrate fiducial; (b) moving a bond head assembly to an offset position such that a first semiconductor element fiducial of the semiconductor element is offset from the first substrate fiducial, the semiconductor element being carried by a bonding tool of the bond head assembly; (c) imaging the first semiconductor element fiducial and the first substrate fiducial with an imaging system of the bond head assembly with the bond head assembly at the offset position; (d) moving the semiconductor element while it is carried by the bonding tool such that the first semiconductor element fiducial is aligned with the first substrate fiducial; and (e) bonding the semiconductor element to the substrate after step (d).

According to other embodiments of the invention, the method recited in the immediately preceding paragraph may have any one or more of the following features: further including a step of determining a position of each of the first semiconductor element fiducial and the first substrate fiducial using the imaging of step (c); the determining of the position of each of the first semiconductor element fiducial and the first substrate fiducial includes determining respective pixel coordinate locations of the imaging system; step (d) includes moving the semiconductor element such that the position of the first semiconductor element fiducial is aligned with the position of the first substrate fiducial; step (d) includes moving the semiconductor element with a motion system configured to move the bonding tool independent of the imaging system; the bond head assembly remains stationary during step (c) and step (d); step (d) includes substeps (d1) moving the semiconductor element to a first alignment position with respect to the substrate, (d2) determining if the first semiconductor element fiducial is aligned with the first substrate fiducial with the semiconductor element at the first alignment position, and (d3) moving the semiconductor element to another alignment position with respect to the substrate if the first semiconductor element fiducial is not aligned with the first substrate fiducial at the first alignment position; substep (d2) includes performing an imaging operation to determine if the first semiconductor element fiducial is aligned with the first substrate fiducial; substep (d2) includes using image processing to determine if alignment criteria are satisfied; step (d) includes a substep (d4), substep (d4) including repeating substeps (d2) and (d3) until the first semiconductor element fiducial is aligned with the first substrate fiducial; step (d) includes at least one of moving the semiconductor element (i) with a rotative motion and (ii) with a translational motion; the substrate includes a second substrate fiducial and the semiconductor element includes a second semiconductor element fiducial, wherein step (c) includes (i) imaging the first semiconductor element fiducial and the first substrate fiducial with the imaging system and (ii) imaging the second semiconductor element fiducial and the second substrate fiducial with the imaging system; step (c) includes (i) imaging the first semiconductor element fiducial and the first substrate fiducial along a first optical path of the imaging system and (ii) imaging the second semiconductor element fiducial and the second substrate fiducial along a second optical path of the imaging system; further including a step of determining an alignment adjustment based on the imaging of step (c) such that the first semiconductor element fiducial will be aligned with the first substrate fiducial when the semiconductor element is moved by the alignment adjustment; the alignment adjustment is related to a difference between (i) a position of the first semiconductor element fiducial and (ii) a position of the first substrate fiducial; step (d) includes moving the semiconductor element by the alignment adjustment; step (c) includes imaging the first semiconductor element fiducial and the first substrate fiducial with a single field of view of the imaging system; step (c) includes imaging the first substrate fiducial through an opening of the bonding tool; step (c) includes imaging the first substrate fiducial through a transparent portion of the bonding tool; step (c) includes imaging of the first substrate fiducial through an optical retarder plate integrated with the imaging system; step (c) includes utilizing an infrared imaging process; the first semiconductor element fiducial is (i) embedded within a body portion of the semiconductor element or (ii) on a surface of the semiconductor element closest to the substrate during step (c); step (e) includes bonding the semiconductor element to the substrate using a hybrid bonding process.

According to another exemplary embodiment of the invention, a method of bonding a semiconductor element to a substrate is provided. The method includes the steps of: (a) supporting the substrate with a support structure, the substrate including a first substrate fiducial and a second substrate fiducial; (b) moving a bond head assembly to an offset position such that a first semiconductor element fiducial and a second semiconductor element fiducial of the semiconductor element are offset from the first substrate fiducial and the second substrate fiducial, respectively, the semiconductor element being carried by a bonding tool of the bond head assembly, the bond head assembly including an imaging system; (c) imaging (i) the first semiconductor element fiducial and the first substrate fiducial, and (ii) the second semiconductor element fiducial and the second substrate fiducial with the imaging system of the bond head assembly with the bond head assembly at the offset position; (d) determining an alignment adjustment based on the imaging of step (c) such that (i) the first semiconductor element fiducial will be aligned with the first substrate fiducial when the semiconductor element is moved by the alignment adjustment and (ii) the second semiconductor element fiducial will be aligned with the second substrate fiducial when the semiconductor element is moved by the alignment adjustment; (e) moving the semiconductor element while it is carried by the bonding tool such that (i) the first semiconductor element fiducial is aligned with the first substrate fiducial and (ii) the second semiconductor element fiducial is aligned with the second substrate fiducial; and (f) bonding the semiconductor element to the substrate after step (e).

According to other embodiments of the invention, the method recited in the immediately preceding paragraph may have any one or more of the following features: step (d) includes determining a position of each of the first semiconductor element fiducial, the second semiconductor element fiducial, the first substrate fiducial, and the second substrate fiducial using the imaging of step (c); the determining of the position of each of the first semiconductor element fiducial, the second semiconductor element fiducial, the first substrate fiducial, and the second substrate fiducial includes determining respective pixel coordinate locations of the imaging system; step (e) includes moving the semiconductor element such that (i) the position of the first semiconductor element fiducial is aligned with the position of the first substrate fiducial and (ii) the position of the second semiconductor element fiducial is aligned with the position of the second substrate fiducial; step (e) includes moving the semiconductor element with a motion system configured to move the bonding tool independent of the imaging system; the bond head assembly remains stationary during step (c), step (d), and step (e); step (e) includes substeps (e1) moving the semiconductor element to a first alignment position with respect to the substrate, (e2) determining (i) if the first semiconductor element fiducial is aligned with the first substrate fiducial with the semiconductor element at the first alignment position, and (ii) if the second semiconductor element fiducial is aligned with the second substrate fiducial with the semiconductor element at the first alignment position, and (e3) moving the semiconductor element to another alignment position with respect to the substrate (i) if the first semiconductor element fiducial is not aligned with the first substrate fiducial at the first alignment position or (ii) if the second semiconductor element fiducial is not aligned with the second substrate fiducial at the first alignment position; substep (e2) includes performing an imaging operation to determine (i) if the first semiconductor element fiducial is aligned with the first substrate fiducial, and (ii) if the second semiconductor element fiducial is aligned with the second substrate fiducial; substep (e2) includes using image processing to determine if alignment criteria are satisfied; step (e) includes a substep (e4), substep (e4) includes repeating substeps (e2) and (e3) until (i) the first semiconductor element fiducial is aligned with the first substrate fiducial, and (ii) the second semiconductor element fiducial is aligned with the second substrate fiducial; step (e) includes at least one of moving the semiconductor element (i) with a rotative motion and (ii) with a translational motion; step (c) includes (i) imaging the first semiconductor element fiducial and the first substrate fiducial along a first optical path of the imaging system and (ii) imaging the second semiconductor element fiducial and the second substrate fiducial along a second optical path of the imaging system; the alignment adjustment is related to (i) a difference between a position of the first semiconductor element fiducial and a position of the first substrate fiducial and (ii) a difference between a position of the second semiconductor element fiducial and a position of the second substrate fiducial; step (e) includes moving the semiconductor element by the alignment adjustment; step (c) includes (i) imaging the first semiconductor element fiducial and the first substrate fiducial with a single field of view of the imaging system, and (ii) imaging the second semiconductor element fiducial and the second substrate fiducial with another single field of view of the imaging system; step (c) includes imaging (i) the first substrate fiducial and (ii) the second substrate fiducial through an opening of the bonding tool; step (c) includes imaging the first substrate fiducial and the second substrate fiducial through a transparent portion of the bonding tool; step (c) includes imaging of the first substrate fiducial and the second substrate fiducial through an optical retarder plate integrated with the imaging system; step (f) includes bonding the semiconductor element to the substrate using a hybrid bonding process.

According to yet another exemplary embodiment of the invention, a system for bonding a semiconductor element to a substrate is provided. The system includes a support structure for supporting the substrate, the substrate including a substrate fiducial. The system also includes a bond head assembly for bonding the semiconductor element to the substrate, the semiconductor element including a semiconductor element fiducial. The bond head assembly includes a bonding tool configured to carry the semiconductor element. The bond head assembly also includes an imaging system configured for simultaneously imaging the semiconductor element fiducial and the substrate fiducial. The imaging system includes an optical retarder plate in an optical path of the imaging system for imaging the substrate fiducial. The imaging system is configured for imaging the semiconductor element fiducial and the substrate fiducial at an offset position where the semiconductor element fiducial is offset from the substrate fiducial. The imaging system is configured for imaging the semiconductor element fiducial in an alignment position where the semiconductor element fiducial is aligned with the substrate fiducial.

According to other embodiments of the invention, the system recited in the immediately preceding paragraph may have any one or more of the following features: the bonding tool includes a body portion, the body portion defining an opening through which the semiconductor element fiducial and the substrate fiducial are imaged; the bonding tool includes a body portion, the body portion defining a transparent region through which the semiconductor element fiducial and the substrate fiducial are imaged; the bond head assembly includes a motion system for moving the semiconductor element independent of the imaging system, the motion system configured for moving the semiconductor element between the offset position and the alignment position; the system uses a hybrid bonding process for bonding the semiconductor element to the substrate.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1F are block diagram side and top views of a system for bonding a semiconductor element to a substrate in accordance with an exemplary embodiment of the invention;

FIG. 2 is a block diagram side view of another system for bonding a semiconductor element to a substrate in accordance with another exemplary embodiment of the invention; and

FIG. 3 is a flow diagram illustrating various methods of bonding a semiconductor element to a substrate in accordance with various exemplary embodiments of the invention.

### DETAILED DESCRIPTION

Certain embodiments of the invention are configured to enable accurate placement of a semiconductor element on a target substrate by aligning fiducials on the semiconductor element and fiducials on a target substrate. Aspects of the invention may have particular applicability in connection with hybrid bonding, thermocompression bonding, flip chip bonding, etc. For example, aspects of the invention may be used in copper to copper (Cu—Cu) bonding processes (i.e., wherein copper conductive structures of a semiconductor element are bonded to copper conductive structures of a substrate).

A challenge that may exist in certain bonding applications is related to circuitry in the semiconductor element. For example, the alignment schemes illustrated and described in U.S. Pat. No. 12,438,117 may be difficult because of such circuitry. That is, such circuitry may present an obstacle to imaging (e.g., using infrared light) a substrate fiducial below the semiconductor element. Aspects of the invention address this challenge by imaging the semiconductor element fiducial and the substrate fiducial at an “offset position”.

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semiconductor chip, a semiconductor wafer, a BGA substrate, a semiconductor element, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which a semiconductor element may be bonded. Exemplary substrates include, for example, a leadframe, a PCB, a carrier, a module, a semiconductor chip, a semiconductor wafer, a panel, a BGA substrate, another semiconductor element, or any other type of substrate.

As used herein, the term “bonding” refers to any type of bonding (or attaching) of a semiconductor element to another structure (e.g., a substrate). For example, die bonding includes traditional die bonding (die attach), thermocompression bonding, flip chip bonding, pick and place bonding, hybrid bonding, etc. As used herein “hybrid bonding” refers to a form of flip chip bonding including (i) a dielectric bond formed between a surface of the semiconductor element and a surface of the substrate and (ii) a conductive bond between conductive structures of the semiconductor element and conductive structures of the substrate (e.g., copper to copper bonding, etc.).

Aspects of the invention relate to in situ alignment schemes on die bonding systems. More specifically, aspects of the invention relate to imaging (and/or inspecting) fiducial markings on a semiconductor element and on a substrate at the same time (at an offset position) while the die is held by a bond head above the target surface of the substrate and then moving the semiconductor element to an aligned position.

According to various exemplary embodiments of the invention, an infrared imaging system (such as a near infrared imaging and camera system, or another type of imaging system) can be used to look through a bonding tool (e.g., an infrared transparent bonding tool), a bonding tool holder (e.g., an infrared transparent bonding tool holder), a motion system, a semiconductor element, and/or a substrate, thereby capturing fiducial markings of the semiconductor element and corresponding fiducial markings of the substrate within the same image.

Aspects of the invention relate to using the relative position of a semiconductor element and a substrate (e.g., retrieved from one or more semiconductor element fiducials and substrate fiducials) to adjust the semiconductor element to substrate alignment prior to bonding.

In certain embodiments of the invention, in order to achieve sub-micron level pixel and optical resolution, an imaging system/optical system may provide only a small field of view (i.e., FOV). However, fiducial sets may be spaced quite far apart (i.e., relative to a specific die size). Therefore, according to certain embodiments of the invention, at least two separate cameras or imaging systems may be utilized. Such cameras or imaging systems are desirably mechanically “configurable” with respect to the application specific field of view (FOV) locations.

In accordance with specific embodiments of the invention, a bond head including infrared (or near infrared, NIR) imaging and camera systems are provided, along with an alignment scheme, that allows for fully independent selection of two (or more) FOVs over a whole die area. Using such aspects, a very compact XYZ and θ_{z} fine correction mechanism (e.g., motion system 106) is provided that acts right at the bonding tool and/or bonding tool holder.

Exemplary coarse motion systems (e.g., coarse motion system 108) illustrated and described herein may be, for example, gantry type motion systems. Exemplary fine motion systems (e.g., fine motion system 106) illustrated and described herein may be, for example, piezo actuators (e.g., with nm level resolution). Such fine motion systems may provide, for example, a range of up to 50 μm-200 μm of travel in the x-y plane (although fine motion systems with greater than 200 μm of travel may be used in connection with the invention). Such fine motion systems may move a die 10 μm-20 μm down to bring the die into contact with a substrate in connection with a bonding step. A specific exemplary fine motion system may include two piezo stacks for XYZ fine positioning and use synchronous piezo motions, where a rotational position (e.g., rotation about the Z-axis, that is θ_{z} motion) may be adjusted using differential piezo motions. A fine motion system may include a vacuum interface for holding a bonding tool and/or semiconductor element (e.g., a die).

Such a scheme (e.g., using a coarse motion system and a fine motion system) may be used to provide a high level of accuracy (and efficiency). Large motions may be made using the coarse motion system, and then small adjustments may be made with the fine motion system. Further, there may be a small Z-axis movement after final alignment to complete the bonding step.

Any of a number of fiducial styles (e.g., cross-shaped, circular, octagonal, etc.) may be used as is desired in the specific application. Exemplary fiducials may be approximately 25-50 μm in overall length and/or width (although fiducials of <25 μm and >50 μm may be used in connection with the invention).

To provide fiducial alignment data, an imaging system may be used. In certain exemplary embodiments of the invention, a beam splitter may be used; however, other optical elements are contemplated. In such embodiments (e.g., including a beam splitter), cameras may move along at least two axes to adapt between different fiducial positions. Cameras move along beam axes to compensate for a shift of optical path length. The beam splitter in the bond head transmits beams through the die, whereby the working distance may remain the same independent of the fiducial position. The fields of view (FOV) may be overlapping. Two independent optical paths (in connection with two beam splitter ports) may be used. Each optical path may have, for example, a 1×1 mm FOV. The camera (e.g., an infrared camera) may be motorized for XY FOV positioning, including overlapping FOVs for large or small dies. An imaging system may include multiple cameras for providing multiple optical paths simultaneously.

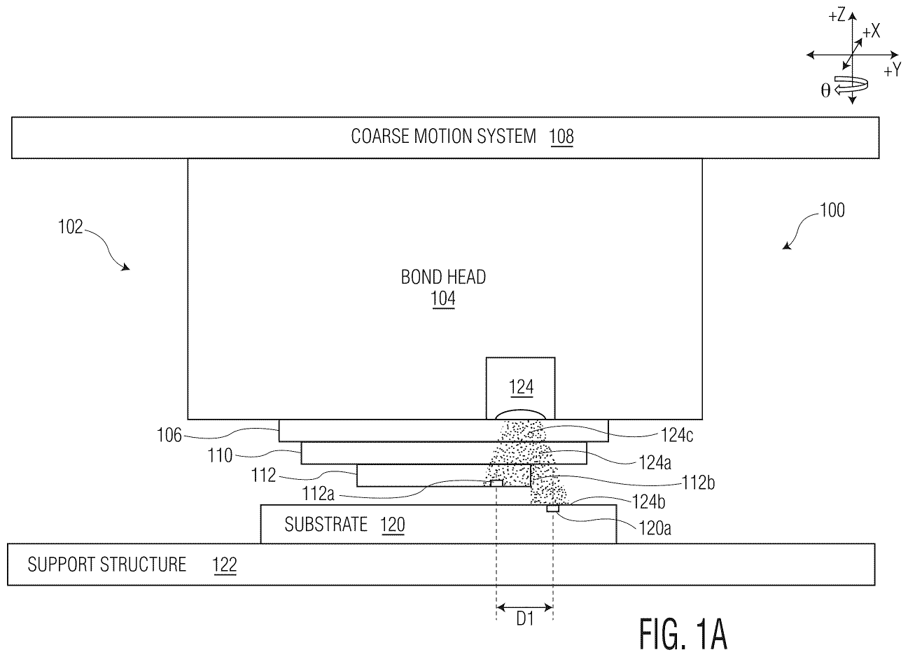

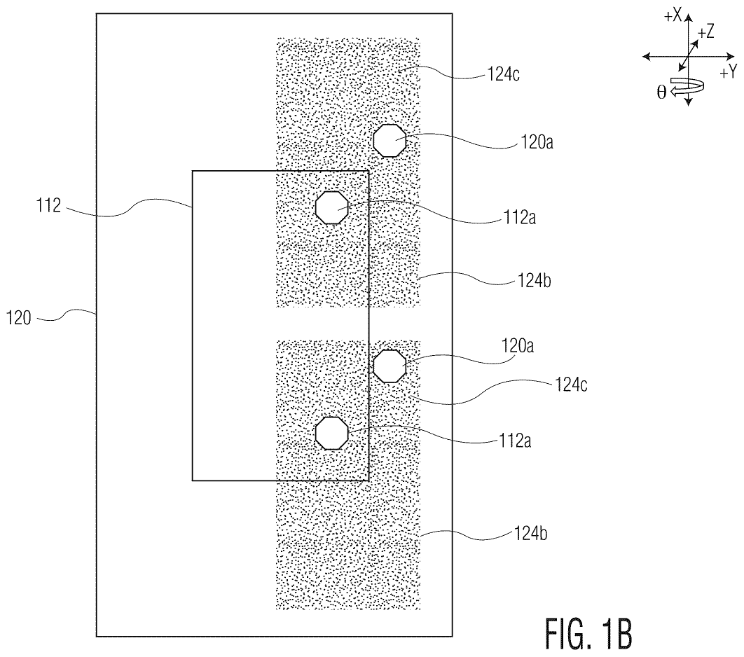

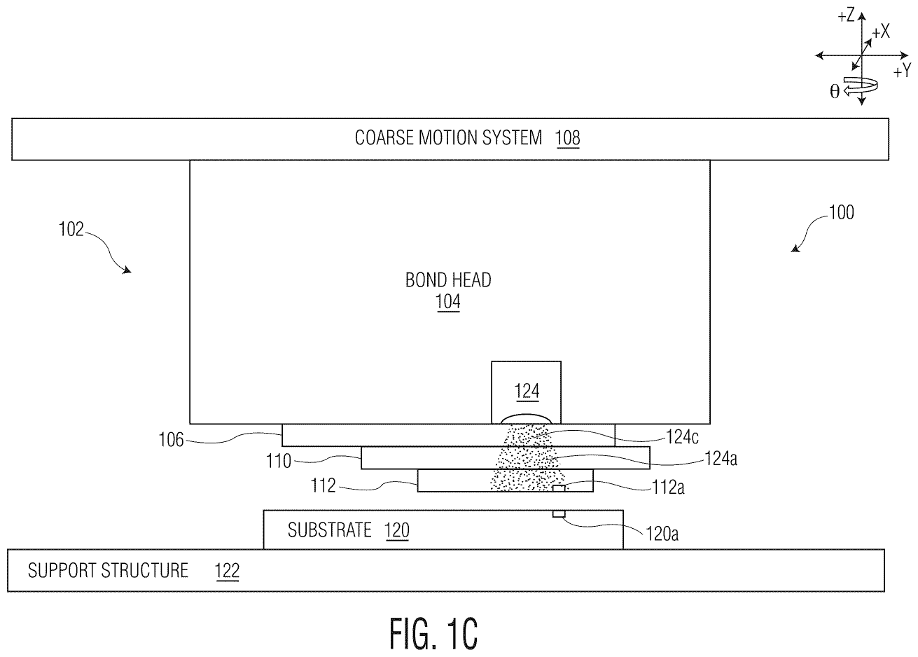

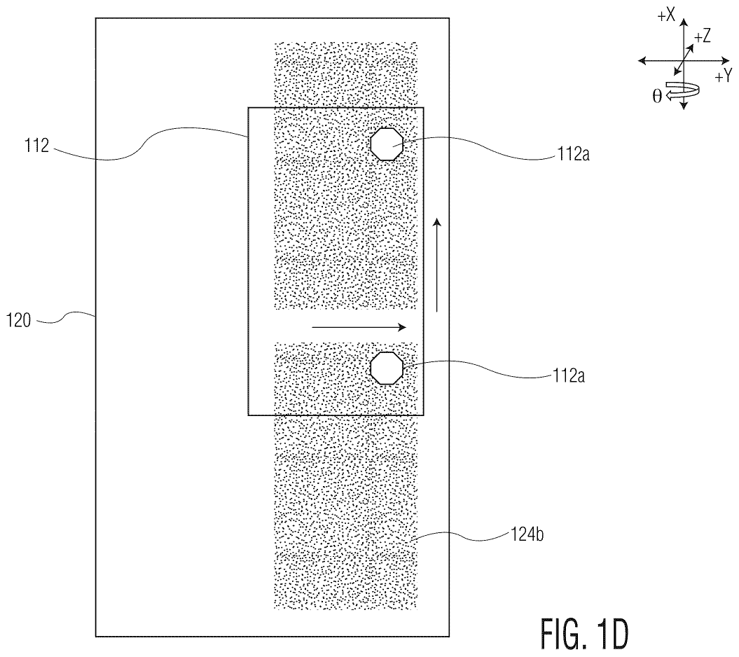

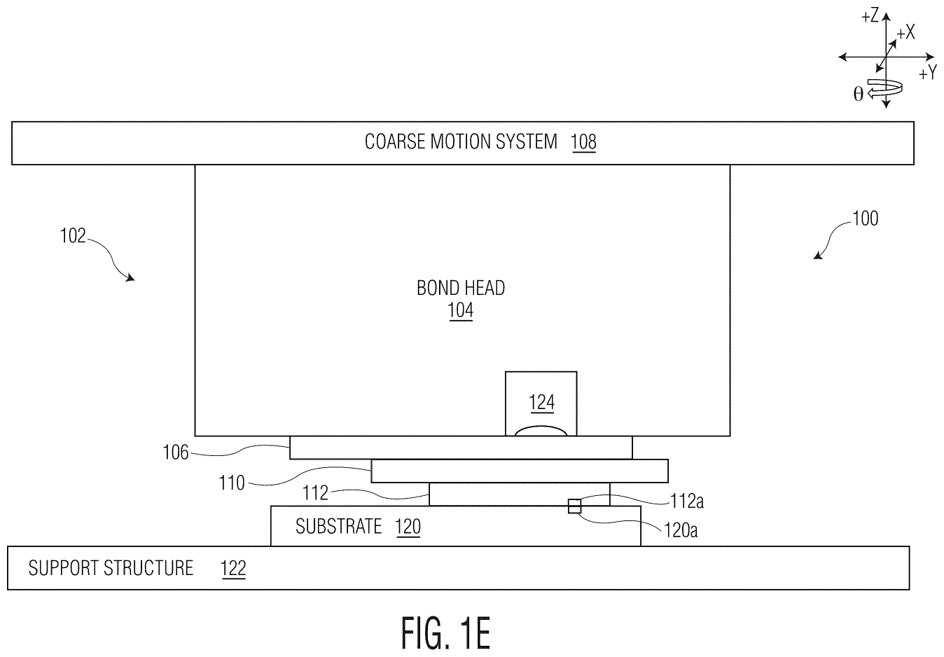

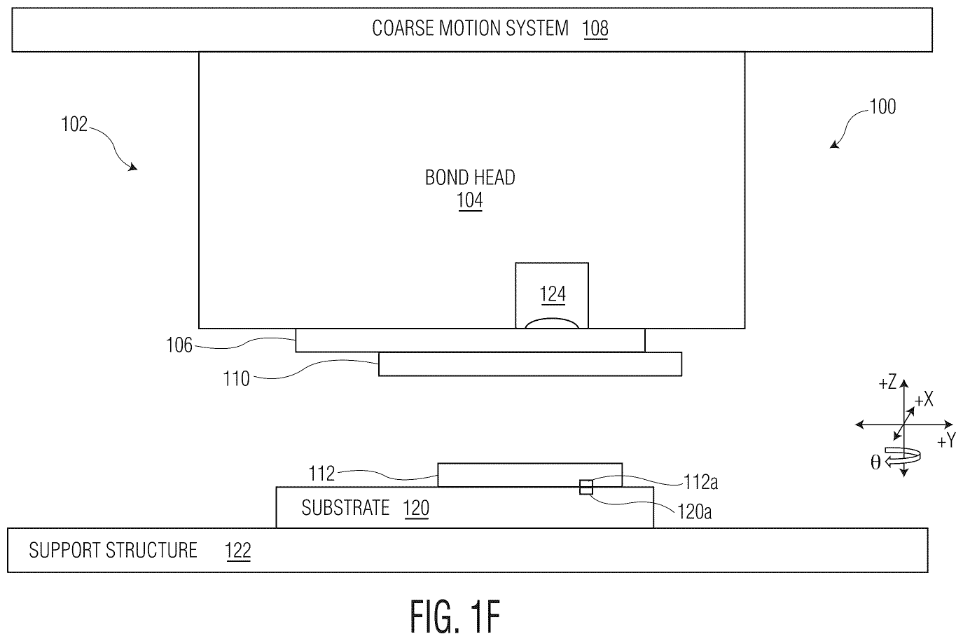

Referring now to the drawings, a system 100 (e.g., a bonding system, a hybrid bonding system, etc.) is illustrated in FIG. 1A. System 100 includes a bond head assembly 102 for bonding a semiconductor element 112 to a substrate 120, and a support structure 122 for supporting substrate 120. Bond head assembly 102 includes a bond head 104, a motion system 106 (e.g., a fine motion system, a piezostack actuator, etc.), and an imaging system 124 carried by bond head assembly 102. Bond head assembly 102 includes (and/or is configured to carry) a bonding tool 110. Bonding tool 110 is configured to hold a semiconductor element 112 prior to bonding semiconductor element 112 to substrate 120 (where bonding tool 110 holds semiconductor element 112 at a holding portion of bonding tool 110, where the holding portion may be formed from an infrared transparent material). Motion system 106 is configured to move bonding tool 110 independent of imaging system 124.

Bond head assembly 102 is supported and carried by a motion system 108 (e.g., a coarse motion system, an X-Y motion system, a gantry, etc.). Bond head assembly 102 is illustrated having carried semiconductor element 112 (e.g., from a die source, such as: a wafer; a tape and reel; a tray; or another die source including a plurality of semiconductor elements) to an offset position D1. In this example, an active side of semiconductor element 112 is facing down towards substrate 120 separated by a gap (e.g., 20-30 μm); however, semiconductor element 112 may also be picked up with the active side facing up. In the illustrated example, semiconductor element 112 includes a semiconductor element fiducial 112a embedded within a body portion of semiconductor element 112 and/or on a surface of semiconductor element 112 closest to substrate 120. It should be understood that semiconductor element 112 may include a plurality of semiconductor element fiducials 112a (e.g., see FIG. 1B). In certain embodiments, semiconductor element fiducial 112a can be imaged utilizing an infrared imaging process.

In FIG. 1A, a side view of bond head assembly 102 is illustrated using imaging system 124 (providing and/or receiving optical energy 124a in a vertical/Z direction along an optical path 124c after having moved semiconductor element 112 to offset position D1. Semiconductor element 112 is offset such that semiconductor element fiducial 112a of semiconductor element 112 is offset from substrate fiducial 120a of substrate 120. Such an offset may be considered to be a pre-alignment offset. Semiconductor element 112 is offset such that an image (e.g., a “top view” image, planar image, etc.) captured by imaging system 124 includes semiconductor element fiducial 112a and a corresponding substrate fiducial 120a (e.g., without needing to image the substrate fiducial 120a through semiconductor element 112). As illustrated, semiconductor element 112 has been moved such that substrate fiducial 120a is positioned to the right (i.e., the +Y direction) of a side 112b of semiconductor element 112 and semiconductor element fiducial 112a is positioned to the left (i.e., the −Y direction) of side 112b.

Using imaging system 124, a position of each of semiconductor element fiducial 112a and substrate fiducial 120a can be determined (e.g., “memorized” or stored in a computer readable medium of system 100). Such positions may be an X-Y position of a coordinate system of system 100 (e.g., a coordinate system of imaging system 124). In certain embodiments, the determining of the positions of each of semiconductor element fiducial 112a and substrate fiducial 120a includes determining respective pixel coordinate locations of imaging system 124. A relative position between each of the semiconductor element fiducial 112a and substrate fiducial 120a can be determined.

Using the position of the semiconductor element fiducial 112a and substrate fiducial 120a (e.g., system positions, pixel coordinate locations, the relative position therebetween, etc.), an alignment adjustment (based on the imaging) can be determined. The alignment adjustment is determined such that semiconductor element fiducial 112a is (or is intended to be) aligned with substrate fiducial 120a when semiconductor element 112 is moved by the alignment adjustment using motion system 106.

Referring now to FIG. 1B, a top view of semiconductor element 112 and substrate 120 of FIG. 1A are illustrated. In the illustrated example, semiconductor element 112 includes a plurality of semiconductor element fiducials 112a and substrate 120 includes a plurality of substrate fiducials 120a. A first semiconductor element fiducial 112a and a first substrate fiducial 120a are illustrated (i.e., at the bottom or “−X” direction of FIG. 1B) being imaged along a first optical path 124c in a first field of view 124b using imaging system 124 (not illustrated). A second semiconductor element fiducial 112a and a second substrate fiducial 120a are illustrated (i.e., at the top or “+X” direction of FIG. 1B) being imaged along a second optical path 124c in a second field of view 124b using imaging system 124 (not illustrated).

Although FIG. 1B illustrates semiconductor element 112 with two semiconductor element fiducials 112a and substrate 120 with two substrate fiducials 120a, it should be understood that a semiconductor element with any number of fiducials and a substrate with any number of fiducials may be used in connection with various embodiments of the invention (e.g., in connection with imaging steps of the invention). Similarly, although octagonal fiducials are illustrated, it should be understood that any shape/geometry of fiducials may be used.

Referring now to FIGS. 1C-1D, semiconductor element 112 has been moved (while semiconductor element 112 is carried by bonding tool 110) to an alignment position (e.g., a first alignment position) such that semiconductor element fiducial 112a is aligned (or intended to be aligned) with substrate fiducial 120a. Semiconductor element 112 has been moved with motion system 106 (e.g., a fine motion system). In certain examples, semiconductor element 112 has been moved by the determined alignment adjustment. An example of the range of the movement of semiconductor element 112 by motion system 106 is between 50-200 μm (e.g., 150 μm). Bond head assembly 102, bond head 104, and imaging system 124 have not moved from FIG. 1A and thus may be considered stationary. After moving semiconductor element 112 to the alignment position, it may be desirable to determine or confirm if semiconductor element fiducial 112a is aligned with substrate fiducial 120a.

Still referring now to FIGS. 1C-1D, imaging system 124 is illustrated imaging semiconductor element fiducial 112a of semiconductor element 112 in order to determine or confirm if semiconductor element fiducial 112a is aligned with substrate fiducial 120a while semiconductor element 112 is at the alignment position (e.g., a first alignment position). After semiconductor element 112 has been moved to the alignment position with motion system 106, a second position (e.g., X-Y position) of semiconductor element fiducial 112a may be determined using imaging system 124. The second position of semiconductor element fiducial 112a may be compared with the previously determined position (e.g., X-Y position) of substrate fiducial 120a. If the second position of semiconductor element fiducial 112a matches the previously determined position of substrate fiducial 120a (e.g., within a certain tolerance alignment, such as +/−25nm), semiconductor element fiducial 112a may be considered to be aligned with substrate fiducial 120a such that semiconductor element 112 can be bonded to substrate 120. In certain embodiments, alignment is determined when each of a plurality of semiconductor element fiducials 112a are aligned within a certain tolerance of corresponding substrate fiducials 120a.

If it is determined that semiconductor element fiducial 112a is not aligned with substrate fiducial 120a with semiconductor element 112 at a first alignment position (e.g., failing to satisfy “alignment criteria”), semiconductor element 112 can be moved to another alignment position. If it is determined that semiconductor element fiducial 112a is not aligned with substrate fiducial 120a with semiconductor element 112 at the another alignment position, semiconductor element 112 can be moved to yet another alignment position, and so forth, until it is determined that semiconductor element fiducial 112a is aligned with substrate fiducial 120a. In certain embodiments, semiconductor element 112 can be moved with a rotative motion and/or with a translational motion.

Referring now to FIG. 1E, semiconductor element 112 is bonded to substrate 120 after semiconductor element 112 has been moved to an alignment position (e.g., a final alignment position). As shown in FIG. 1F, after semiconductor element 112 has been bonded to substrate 120, bonding tool 110 is raised vertically (i.e., along the Z-axis) above semiconductor element 112 (e.g., through motion of bond head assembly 102).

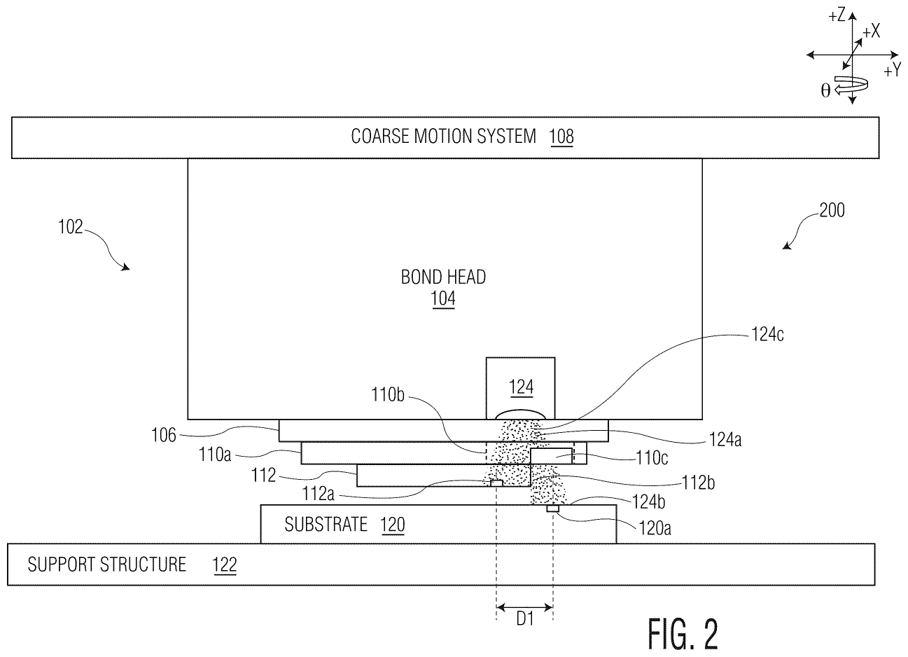

Referring now to FIG. 2, a system 200 (e.g., bonding system) is illustrated. System 200 is the same as system 100 of FIGS. 1A-1F, except a bonding tool 110a is used in lieu of bonding tool 110 and an optical retarder plate 110c is included. Bonding tool 110a defines an opening 110b through which one or more of semiconductor element fiducial 112a and substrate fiducial 120a can be imaged. In certain embodiments, a transparent portion of the bonding tool can be used in lieu of opening 110b.

Bonding tool 110a is illustrated including optical retarder plate 110c. Optical retarder plate 110c may be introduced into optical path 124c of optical energy 124a provided/received by imaging system 124 to improve the imaging of substrate fiducial 120a. When imaging semiconductor element fiducial 112a through semiconductor element 112 and substrate fiducial 120a through air, the optical path lengths may be substantially different (e.g., silicon has a very high index of refraction relative to air). Accordingly, both fiducials may not be in focus at the same time, given a limited depth of field when using a high-resolution imaging system. Such focus issues may get worse with increasing semiconductor element thickness.

Thus, the thickness of optical retarder plate 110c may be modified to compensate for the thickness of semiconductor element 112. Optical retarder plate 110c may be made of the same (or similar) material as semiconductor element 112 and/or may have the same (or similar) thickness as semiconductor element 112. In other embodiments, optical retarder plate 110c may be made of a different material from semiconductor element 112 and/or may have a different thickness from semiconductor element 112. Optical retarder plate 110c may effectively simulate semiconductor element 112 (e.g., simulate the index of refraction or other optical properties) such that optical distortion is minimized/eliminated when taking an image with imaging system 124.

It should be understood that in other embodiments, optical retarder plate 110c may not be included in the bonding tool 110a; rather, for example, optical retarder plate 110c may be integrated with imaging system 124 or another component of bond head assembly 102.

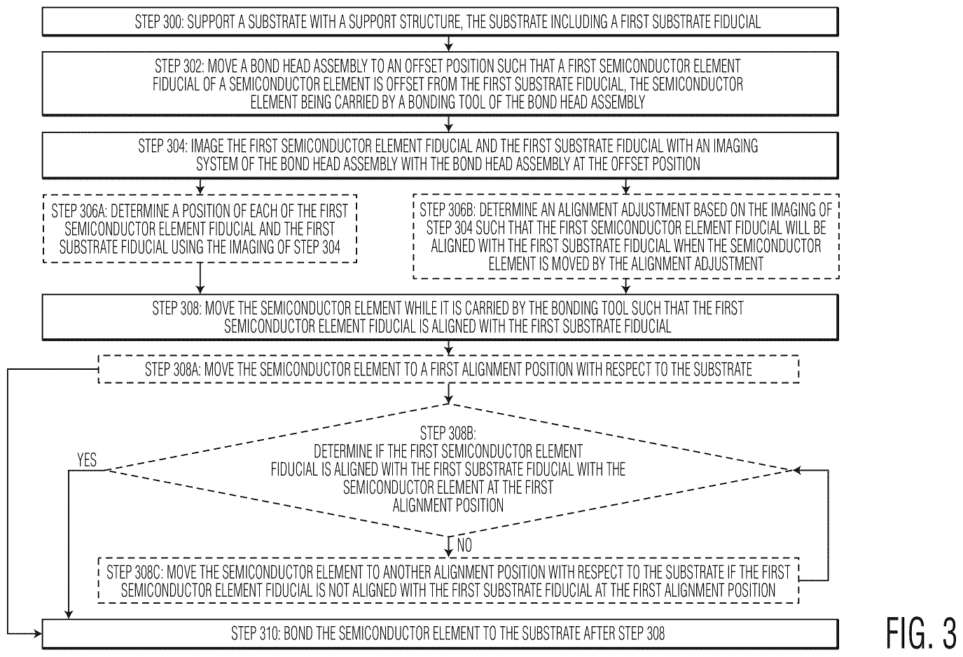

FIG. 3 is a flow diagram illustrating a method of bonding a semiconductor element to a substrate. As is understood by those skilled in the art, certain steps included in the flow diagram may be omitted; certain additional steps may be added; and the order of the steps may be altered from the order illustrated—all within the scope of the invention.

At Step 300, a substrate (e.g., substrate 120) is supported with a support structure (e.g., support structure 122). The substrate includes a first substrate fiducial (e.g., substrate fiducial 120a). In certain embodiments, the substrate includes a second substrate fiducial.

At Step 302, a bond head assembly (e.g., bond head assembly 102) is moved to an offset position (e.g., offset position D1) such that a first semiconductor element fiducial (e.g., semiconductor element fiducial 112a) of the semiconductor element (e.g., semiconductor element 112) is offset from the first substrate fiducial, the semiconductor element being carried by a bonding tool (e.g., bonding tool 110) of the bond head assembly. In certain embodiments, the first semiconductor element fiducial is (i) embedded within a body portion of the semiconductor element and/or (ii) on a surface of the semiconductor element closest to the substrate. In certain embodiments, the semiconductor element includes a second semiconductor element fiducial.

At Step 304, the first semiconductor element fiducial and the first substrate fiducial are imaged with an imaging system (e.g., imaging system 124) of the bond head assembly with the bond head assembly at the offset position. In certain embodiments, Step 304 includes one or more of: imaging the first semiconductor element fiducial and the first substrate fiducial with a single field of view of the imaging system; imaging the first substrate fiducial through an opening of the bonding tool; imaging the first substrate fiducial through a transparent portion of the bonding tool; imaging of the first substrate fiducial through an optical retarder plate integrated with the imaging system; and/or utilizing an infrared imaging process.

In certain embodiments where the substrate includes a second substrate fiducial and the semiconductor element includes a second semiconductor element fiducial, Step 304 includes (i) imaging the first semiconductor element fiducial and the first substrate fiducial with the imaging system and (ii) imaging the second semiconductor element fiducial and the second substrate fiducial with the imaging system. In such embodiments, Step 304 may include (i) imaging the first semiconductor element fiducial and the first substrate fiducial along a first optical path (e.g., optical path 124c) of the imaging system and (ii) imaging the second semiconductor element fiducial and the second substrate fiducial along a second optical path of the imaging system (e.g., see FIG. 1B).

At optional Step 306A, a position of each of the first semiconductor element fiducial and the first substrate fiducial is determined using the imaging of Step 304. For example, an X-Y position (i.e., a lateral and longitudinal position) of each of the first semiconductor element fiducial and the first substrate fiducial is determined. Such an X-Y position may be of a coordinate system of the bond head assembly and/or the imaging system. In certain embodiments, the determining of the position of each of the first semiconductor element fiducial and the first substrate fiducial may include determining respective pixel coordinate locations of the imaging system.

In addition to (or in lieu of) Step 306A, at optional Step 306B, an alignment adjustment is determined based on the imaging of Step 304 such that the first semiconductor element fiducial will be aligned with (or intended to be aligned with) the first substrate fiducial when the semiconductor element is moved by the alignment adjustment.

In certain embodiments where the substrate includes a second substrate fiducial and the semiconductor element includes a second semiconductor element fiducial, optional Step 306B includes determining an alignment adjustment based on the imaging of Step 304 such that (i) the first semiconductor element fiducial will be aligned with the first substrate fiducial when the semiconductor element is moved by the alignment adjustment and (ii) the second semiconductor element fiducial will be aligned with the second substrate fiducial when the semiconductor element is moved by the alignment adjustment.

At Step 308, the semiconductor element is moved while it is carried by the bonding tool such that the first semiconductor element fiducial is aligned with the first substrate fiducial. In certain embodiments, Step 308 may include substeps 308A, 308B, and 308C. At Step 308A, the semiconductor element is moved to a first alignment position with respect to the substrate. At Step 308B, it is determined (e.g., using imaging of the imaging system) if the first semiconductor element fiducial is aligned with the first substrate fiducial with the semiconductor element at the first alignment position. At Step 308C, the semiconductor element is moved to another alignment position with respect to the substrate if the first semiconductor element fiducial is not aligned with the first substrate fiducial at the first alignment position. In certain embodiments, Step 308B and Step 308C are repeated in an iterative process (e.g., until the first semiconductor element fiducial is aligned with the first substrate fiducial). In some examples, Step 308B is a decision block, where if it is determined that “yes” the semiconductor element fiducial and substrate fiducial are aligned, then the semiconductor element is bonded to substrate at Step 310; if it is determined that “no” the semiconductor element fiducial and substrate fiducial are not aligned, then the semiconductor element is moved to another alignment position at Step 308C. In certain embodiments, Step 308B includes performing an imaging operation to determine if the first semiconductor element fiducial is aligned with the first substrate fiducial (e.g., imaging to determine if the position of the first semiconductor element fiducial is aligned with the position of the first substrate fiducial). In certain embodiments, Step 308B includes using image processing to determine if alignment criteria are satisfied.

In certain embodiments where the substrate includes a second substrate fiducial and the semiconductor element includes a second semiconductor element fiducial, Step 308 includes moving the semiconductor element while it is carried by the bonding tool such that (i) the first semiconductor element fiducial is aligned with the first substrate fiducial and (ii) the second semiconductor element fiducial is aligned with the second substrate fiducial.

At Step 310, the semiconductor element is bonded to the substrate after Step 308. For example, the bonding of the semiconductor element to the substrate in Step 310 may utilize a hybrid bonding process, a thermocompression bonding process, a flip chip bonding process, etc.

Although the invention is illustrated and described herein with reference to an imaging system integrated with (and/or carried by) a bond head assembly, the invention is not so limited. For example, an imaging system could be utilized that is not integrated with (and/or carried by) a bond head assembly. Of course, in such an application, the relative motion of the system components may differ from that shown herein (e.g., the alignment adjustment may be accomplished by moving the bond head assembly without the need for a separate motion system 106).

Although the invention is illustrated and described herein with reference to specific embodiments, the invention is not intended to be limited to the details shown. Rather, various modifications may be made in the details within the scope and range of equivalents of the claims and without departing from the invention.

Claimed:

1. A method of bonding a semiconductor element to a substrate, the method comprising the steps of:
(a) supporting the substrate with a support structure, the substrate including a first substrate fiducial;
(b) moving a bond head assembly to an offset position such that a first semiconductor element fiducial of the semiconductor element is offset from the first substrate fiducial, the semiconductor element being carried by a bonding tool of the bond head assembly;
(c) imaging the first semiconductor element fiducial and the first substrate fiducial with an imaging system of the bond head assembly with the bond head assembly at the offset position;
(d) moving the semiconductor element while it is carried by the bonding tool such that the first semiconductor element fiducial is aligned with the first substrate fiducial; and
(e) bonding the semiconductor element to the substrate after step (d).

2. The method of claim 1 further comprising a step of determining a position of each of the first semiconductor element fiducial and the first substrate fiducial using the imaging of step (c).

3. The method of claim 2 wherein the determining of the position of each of the first semiconductor element fiducial and the first substrate fiducial includes determining respective pixel coordinate locations of the imaging system.

4. The method of claim 2 wherein step (d) includes moving the semiconductor element such that the position of the first semiconductor element fiducial is aligned with the position of the first substrate fiducial.

5. The method of claim 1 wherein step (d) includes moving the semiconductor element with a motion system configured to move the bonding tool independent of the imaging system.

6. The method of claim 5 wherein the bond head assembly remains stationary during step (c) and step (d).

7. The method of claim 1 wherein step (d) includes substeps
(d1) moving the semiconductor element to a first alignment position with respect to the substrate,
(d2) determining if the first semiconductor element fiducial is aligned with the first substrate fiducial with the semiconductor element at the first alignment position, and
(d3) moving the semiconductor element to another alignment position with respect to the substrate if the first semiconductor element fiducial is not aligned with the first substrate fiducial at the first alignment position.

8. The method of claim 7 wherein substep (d2) includes performing an imaging operation to determine if the first semiconductor element fiducial is aligned with the first substrate fiducial.

9. The method of claim 8 wherein substep (d2) includes using image processing to determine if alignment criteria are satisfied.

10. The method of claim 7 wherein step (d) includes a substep (d4), substep (d4) including repeating substeps (d2) and (d3) until the first semiconductor element fiducial is aligned with the first substrate fiducial.

11. The method of claim 1 wherein step (d) includes at least one of moving the semiconductor element (i) with a rotative motion and (ii) with a translational motion.

12. The method of claim 1 wherein the substrate includes a second substrate fiducial and the semiconductor element includes a second semiconductor element fiducial, wherein step (c) includes (i) imaging the first semiconductor element fiducial and the first substrate fiducial with the imaging system and (ii) imaging the second semiconductor element fiducial and the second substrate fiducial with the imaging system.

13. The method of claim 12 wherein step (c) includes (i) imaging the first semiconductor element fiducial and the first substrate fiducial along a first optical path of the imaging system and (ii) imaging the second semiconductor element fiducial and the second substrate fiducial along a second optical path of the imaging system.

14. The method of claim 1 further comprising a step of determining an alignment adjustment based on the imaging of step (c) such that the first semiconductor element fiducial will be aligned with the first substrate fiducial when the semiconductor element is moved by the alignment adjustment.

15. The method of claim 14 wherein the alignment adjustment is related to a difference between (i) a position of the first semiconductor element fiducial and (ii) a position of the first substrate fiducial.

16. The method of claim 15 wherein step (d) includes moving the semiconductor element by the alignment adjustment.

17. The method of claim 1 wherein step (c) includes imaging the first semiconductor element fiducial and the first substrate fiducial with a single field of view of the imaging system.

18. The method of claim 1 wherein step (c) includes imaging the first substrate fiducial through an opening of the bonding tool.

19. (canceled)

20. (canceled)

21. (canceled)

22. (canceled)

23. (canceled)

24. A method of bonding a semiconductor element to a substrate, the method comprising the steps of:
(a) supporting the substrate with a support structure, the substrate including a first substrate fiducial and a second substrate fiducial;
(b) moving a bond head assembly to an offset position such that a first semiconductor element fiducial and a second semiconductor element fiducial of the semiconductor element are offset from the first substrate fiducial and the second substrate fiducial, respectively, the semiconductor element being carried by a bonding tool of the bond head assembly, the bond head assembly including an imaging system;
(c) imaging (i) the first semiconductor element fiducial and the first substrate fiducial, and (ii) the second semiconductor element fiducial and the second substrate fiducial with the imaging system of the bond head assembly with the bond head assembly at the offset position;
(d) determining an alignment adjustment based on the imaging of step (c) such that (i) the first semiconductor element fiducial will be aligned with the first substrate fiducial when the semiconductor element is moved by the alignment adjustment and (ii) the second semiconductor element fiducial will be aligned with the second substrate fiducial when the semiconductor element is moved by the alignment adjustment;
(e) moving the semiconductor element while it is carried by the bonding tool such that (i) the first semiconductor element fiducial is aligned with the first substrate fiducial and (ii) the second semiconductor element fiducial is aligned with the second substrate fiducial; and
(f) bonding the semiconductor element to the substrate after step (e).

25. (canceled)

26. (canceled)

27. (canceled)

28. (canceled)

29. (canceled)

30. (canceled)
(e1) moving the semiconductor element to a first alignment position with respect to the substrate,
(e2) determining (i) if the first semiconductor element fiducial is aligned with the first substrate fiducial with the semiconductor element at the first alignment position, and (ii) if the second semiconductor element fiducial is aligned with the second substrate fiducial with the semiconductor element at the first alignment position, and
(e3) moving the semiconductor element to another alignment position with respect to the substrate (i) if the first semiconductor element fiducial is not aligned with the first substrate fiducial at the first alignment position or (ii) if the second semiconductor element fiducial is not aligned with the second substrate fiducial at the first alignment position.

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. A system for bonding a semiconductor element to a substrate, the system comprising:
a support structure for supporting the substrate, the substrate including a substrate fiducial; and
a bond head assembly for bonding the semiconductor element to the substrate, the semiconductor element including a semiconductor element fiducial, the bond head assembly including
a bonding tool configured to carry the semiconductor element, and
an imaging system configured for simultaneously imaging the semiconductor element fiducial and the substrate fiducial, the imaging system including an optical retarder plate in an optical path of the imaging system for imaging the substrate fiducial, the imaging system configured for imaging the semiconductor element fiducial and the substrate fiducial at an offset position where the semiconductor element fiducial is offset from the substrate fiducial, the imaging system configured for imaging the semiconductor element fiducial in an alignment position where the semiconductor element fiducial is aligned with the substrate fiducial.

44. (canceled)

45. (canceled)

46. (canceled)

47. (canceled)
